(19) United States
(12) Patent Application Publication
(10) Pub. No.: US 2013/0049060 A1
(43) Pub. Date: Feb. 28, 2013

(54) LIGHT-EMITTING DIODE STRUCTURE AND METHOD FOR MANUFACTURING THE SAME

(71) Applicants: Kuo-Hui Yu, Tainan (TW); Chang-Hsin Chu, Tainan (TW)

(72) Inventors: Kuo-Hui Yu, Tainan (TW); Chang-Hsin Chu, Tainan (TW)

(73) Assignee: CHI MEI LIGHTING TECHNOLOGY CORP., Tainan (TW)

(21) Appl. No.: 13/397,929

(22) Filed: Feb. 16, 2012

(30) Foreign Application Priority Data
Aug. 22, 2011 (TW) 100129991

(51) Int. Cl. H01L 33/42

(52) U.S. Cl. 257/99; 438/22; 257/E33.064

(57) ABSTRACT

A light-emitting diode structure. In one embodiment, the light-emitting diode structure includes an insulation substrate, a light-emitting structure having a first electrical semiconductor layer, a light-emitting layer, and a second electrical semiconductor layer successively stacked on the insulating substrate and containing a first electrode pad region, a second electrode pad region, and a light-emitting region, a first and second electrical electrode pad respectively disposed on the first and second electrode pad region, a second electrical conducting finger disposed on the light-emitting structure and connected to the second electrical electrode pad and the second electrical semiconductor layer, and a first insulating layer for insulating the second electrical conducting finger from the first electrical semiconductor layer and the light-emitting layer. A bottom surface of the second electrical electrode pad is located below an upper surface of the second electrical semiconductor layer.

### CROSS-REFERENCE TO RELATED APPLICATIONS

This non-provisional application claims priority under 35 U.S.C. §119(a) on Patent Application No. 100129991 filed in Taiwan, R.O.C. on Aug. 22, 2011, the entire contents of which are hereby incorporated by reference.

Some references, if any, which may include patents, patent applications and various publications, are cited in a reference list and discussed in the description of this invention. The citation and/or discussion of such references is provided merely to clarify the description of the present invention and is not an admission that any such reference is “prior art” to the invention described herein. All references listed, cited and/or discussed in this specification are incorporated herein by reference in their entireties and to the same extent as if each reference was individually incorporated by reference.

### FIELD OF THE INVENTION

The present invention relates to a light-emitting structure, and more particularly, to a light-emitting diode (LED) structure and a method for manufacturing the same.

### BACKGROUND OF THE INVENTION

FIG. 1 is a sectional view of a conventional LED structure. Referring to FIG. 1, the conventional LED structure 100 includes a substrate 102, an n-type semiconductor layer 104, a light-emitting layer 106, a p-type semiconductor layer 108, a current blocking layer 110, a transparent conducting layer 112, an n-type electrode pad 114, a p-type electrode pad 116, and two connecting wires 120 and 122.

In the LED structure 100, the n-type semiconductor layer 104, the light-emitting layer 106, and the p-type semiconductor layer 108 are stacked on the substrate 102 successively. Moreover, the transparent conducting layer 112 is stacked on the p-type semiconductor layer 108. The p-type electrode pad 116 is disposed on a part of the transparent conducting layer 112. The current blocking layer 110 is located on the p-type semiconductor layer 108 right below the p-type electrode pad 116, so as to block a current directly flowing from the p-type electrode pad 116 to the p-type semiconductor layer 108 right below.

A stacking structure of the n-type semiconductor layer 104, the light-emitting layer 106, the p-type semiconductor layer 108, the current blocking layer 110, and the transparent conducting layer 112 is mesa-defined to remove parts of the transparent conducting layer 112, the p-type semiconductor layer 108, the light-emitting layer 106, and the n-type semiconductor layer 104 to form a mesa 118. The n-type electrode pad 114 is located in an exposed region of the mesa-defined n-type semiconductor layer 104. The connection wires 120 and 122 electrically connect the n-type electrode pad 114 and the p-type electrode pad 116 to two electrical electrodes of an external power source, respectively.

Referring to FIG. 1, in the conventional LED structure 100, structures below the p-type electrode pad 116 are successively the transparent conducting layer 112, the current blocking layer 110, the p-type semiconductor layer 108, the light-emitting layer 106, and the n-type semiconductor layer 104. In another aspect, a structure below the n-type electrode pad 114 is only the n-type semiconductor layer 104. Since structure layers below the n-type electrode pad 114 and the p-type electrode pad 116 are different, during wire bonding, a color aberration occurs between the n-type electrode pad 114 and the p-type electrode pad 116, resulting in an identification problem of a wire-bonding machine.

Moreover, a problem of adhesiveness between different extra material layers and between the extra material layers and an epitaxial layer occurs due to the existence of stress. Many material layers are located below the p-type electrode pad 116, so that the problem of adhesiveness on the p-type electrode pad 116 caused by the stress is especially obvious. For example, a peeling phenomenon may occur on interfaces between the p-type electrode pad 116 and the transparent conducting layer 112, between the transparent conducting layer 112 and the current blocking layer 110, and between the current blocking layer 110 and the p-type semiconductor layer 108 due to undesirable adhesiveness. If the circumstance is serious, the p-type electrode pad 116 is fallen off, and the whole LED structure 100 becomes invalid.

Therefore, a heretofore unaddressed need exists in the art to address the aforementioned deficiencies and inadequacies.

### SUMMARY OF THE INVENTION

In one aspect, the present invention is directed to an LED structure and a method for manufacturing the same, in which both a first electrical electrode pad and a second electrical electrode pad are disposed on a surface of a first electrical semiconductor layer, and an insulating layer is used to electrically insulate a region below the second electrical electrode pad from the first electrical electrode pad and a light-emitting region, thereby greatly reducing the probability of peeling of the second electrode pad caused by the stress of material layers.

In another aspect, the present invention is directed to an LED structure and a method for manufacturing the same, in which structures below a first electrode pad and a second electrode pad are the same, thereby effectively avoiding the color aberration problem of the electrode pads.

In one embodiment, an LED structure according to the present invention includes: an insulating substrate, a light-emitting structure, a first electrical electrode pad, a second electrical electrode pad, a second electrical conducting finger, and a first insulating layer. The light-emitting structure includes a first electrical semiconductor layer, a light-emitting layer, and a second electrical semiconductor layer successively stacked on the insulating substrate. The light-emitting structure includes a first electrode pad region, a second electrode pad region, and a light-emitting region, and the first electrical semiconductor layer and the second electrical semiconductor layer have different electrical properties. The first electrical electrode pad is disposed on the first electrode pad region. The second electrical electrode pad is disposed on the second electrode pad region, in which a bottom surface of the second electrical electrode pad is located below an upper surface of the second electrical semiconductor layer. The second electrical conducting finger is disposed on the light-emitting structure, connected to the second electrical electrode pad, and electrically connected to the second electrical semiconductor layer. The first insulating layer insulates the second electrical conducting finger from the first electrical semiconductor layer and the light-emitting layer in the light-emitting region.

In an embodiment of the present invention, the light-emitting region includes a mesa structure formed by the first electrical semiconductor layer, the light-emitting layer, and the second electrical semiconductor layer.

In another embodiment of the present invention, a width of the second electrical electrode pad is greater than that of the second electrical conducting finger.

In yet another embodiment of the present invention, both the first electrical electrode pad and the second electrical electrode pad are located in an exposed region of the first electrical semiconductor layer.

In still another embodiment of the present invention, the LED structure further includes a transparent conducting layer disposed on the second electrical semiconductor layer in the light-emitting region, wherein the transparent conducting layer is located between the second electrical conducting finger and the second electrical semiconductor layer.

In still another embodiment of the present invention, the first insulating layer extends below a part of the second electrical conducting finger in the light-emitting region.

In still another embodiment of the present invention, the first insulating layer extends below the whole second electrical conducting finger in the light-emitting region, and a part of the transparent conducting layer is located between the first insulating layer and the second electrical conducting finger.

In still another embodiment of the present invention, the light-emitting structure includes an isolating trench, at least located between the second electrical electrode pad and the light-emitting region and penetrating the light-emitting structure to expose a part of the insulating substrate.

In still another embodiment of the present invention, the isolating trench entirely surrounds the second electrical electrode pad.

In still another embodiment of the present invention, the isolating trench entirely surrounds the light-emitting region and the first electrical electrode pad.

In still another embodiment of the present invention, the first insulating layer is formed in at least a part of the isolating trench.

In still another embodiment of the present invention, the first insulating layer is filled in a whole region of the isolating trench.

In still another embodiment of the present invention, the LED structure further includes a second insulating layer. The second insulating layer is filled in the isolating trench, and the first insulating layer extends from the upper surface of the second electrical semiconductor layer and through a side wall of the light-emitting region and the second insulating layer.

In still another embodiment of the present invention, in the light-emitting region, the second electrical conducting finger is located on a side wall of the light-emitting region and the upper surface of the second electrical semiconductor layer.

In still another embodiment of the present invention, the first insulating layer extends from the upper surface of the second electrical semiconductor layer to the second electrode pad region through a side wall of the light-emitting region, and the second electrical electrode pad is entirely located on the first insulating layer.

In still another embodiment of the present invention, the first insulating layer located in the second electrode pad region is substantially located on the same plane.

In still another embodiment of the present invention, structures below the second electrical electrode pad and the first electrical electrode pad are the same.

In a further aspect, a method for manufacturing an LED structure according the present invention includes the following steps. A light-emitting structure is formed on an insulating substrate. The light-emitting structure includes a first electrical semiconductor layer, a light-emitting layer, and a second electrical semiconductor layer successively stacked on the insulating substrate. The light-emitting structure includes a first electrode pad region, a second electrode pad region, and a light-emitting region. The first electrical semiconductor layer and the second electrical semiconductor layer have different electrical properties. A first insulating layer is formed to extend on a part of the light-emitting region and a part of the second electrode pad region. A first electrical electrode pad is formed on the first electrode pad region. A second electrical electrode pad is formed on the second electrode pad region. A bottom surface of the second electrical electrode pad is located below an upper surface of the second electrical semiconductor layer. A second electrical conducting finger is formed on the light-emitting structure, and is connected to the second electrical electrode pad. The second electrical conducting finger is electrically connected to the second electrical semiconductor layer.

In one embodiment of the present invention, between the step of forming the light-emitting structure and the step of forming the first insulating layer, the method for manufacturing an LED structure further includes forming a transparent conducting layer on the second electrical semiconductor layer in the light-emitting region. The transparent conducting layer is located between the second electrical conducting finger and the second electrical semiconductor layer.

In another embodiment of the present invention, the first insulating layer extends below the whole second electrical conducting finger in the light-emitting region, and a part of the transparent conducting layer is located between the first insulating layer and the second electrical conducting finger.

In yet another embodiment of the present invention, between the step of forming the light-emitting structure and the step of forming the first insulating layer, the method for manufacturing an LED structure further includes forming an isolating trench, at least located between the second electrical electrode pad and the light-emitting region and penetrating the light-emitting structure to expose a part of the insulating substrate.

In still another embodiment of the present invention, between the step of forming the isolating trench and the step of forming the first insulating layer, the method for manufacturing an LED structure further includes forming a second insulating layer to be filled in the isolating trench. The first insulating layer extends through a side wall of the light-emitting region and the second insulating layer from the upper surface of the second electrical semiconductor layer.

In still another embodiment of the present invention, the first insulating layer extends from the upper surface of the second electrical semiconductor layer to the second electrode pad region through a side wall of the light-emitting region, and the second electrical electrode pad is entirely located on the first insulating layer.

These and other aspects of the present invention will become apparent from the following description of the preferred embodiment taken in conjunction with the following drawings, although variations and modifications therein may be effected without departing from the spirit and scope of the novel concepts of the disclosure.

### BRIEF DESCRIPTION OF THE DRAWINGS

The accompanying drawings illustrate one or more embodiments of the invention and together with the written description, serve to explain the principles of the invention. Wherever possible, the same reference numbers are used throughout the drawings to refer to the same or like elements of an embodiment, and wherein:

FIG. 1 is a sectional view of a conventional LED structure;

FIG. 2A to FIG. 2D are top views of a process of manufacturing an LED structure according to one embodiment of the present invention;

FIG. 3A to FIG. 3D are sectional views of the process of manufacturing an LED structure according to the embodiment of the present invention;

FIG. 3E is a sectional view of an LED structure taken along a section line BB′ of FIG. 2D;

FIG. 3F is a sectional view of an LED structure taken along a section line CC′ of FIG. 2D;

FIG. 4A is a top view of an LED structure according to another embodiment of the present invention;

FIG. 4B is a sectional view of an LED structure taken along a section line DD′ of FIG. 4A;

FIG. 5A is a top view of an LED structure according to yet another embodiment of the present invention;

FIG. 5B is a sectional view of an LED structure taken along a section line EE′ of FIG. 5A;

FIG. 6A is a top view of an LED structure according to still another embodiment of the present invention;

FIG. 6B is a sectional view of an LED structure taken along a section line FF′ of FIG. 6A;

FIG. 7A is a top view of an LED structure according to still another embodiment of the present invention; and

FIG. 7B is a sectional view of an LED structure taken along a section line GG′ of FIG. 7A.

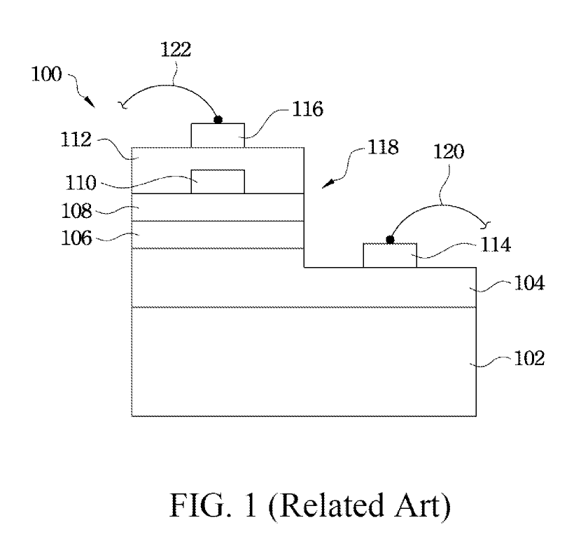

### DETAILED DESCRIPTION OF THE INVENTION

The present invention is more particularly described in the following examples that are intended as illustrative only since numerous modifications and variations therein will be apparent to those skilled in the art. Various embodiments of the invention are now described in detail. Referring to the drawings, like numbers indicate like components throughout the views. As used in the description herein and throughout the claims that follow, the meaning of “a”, “an”, and “the” includes plural reference unless the context clearly dictates otherwise. Also, as used in the description herein and throughout the claims that follow, the meaning of “in” includes “in” and “on” unless the context clearly dictates otherwise. Moreover, titles or subtitles may be used in the specification for the convenience of a reader, which shall have no influence on the scope of the present invention.

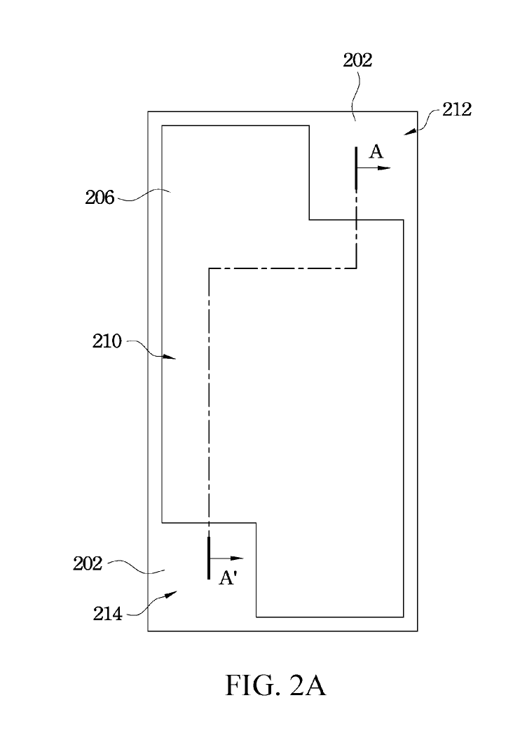

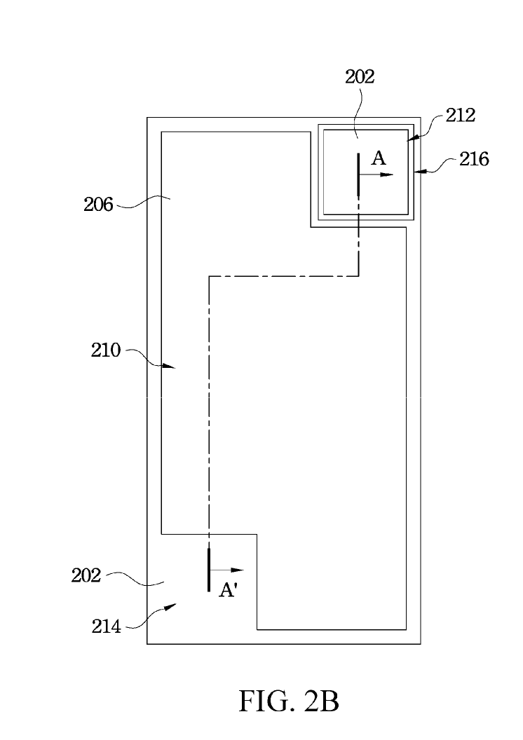

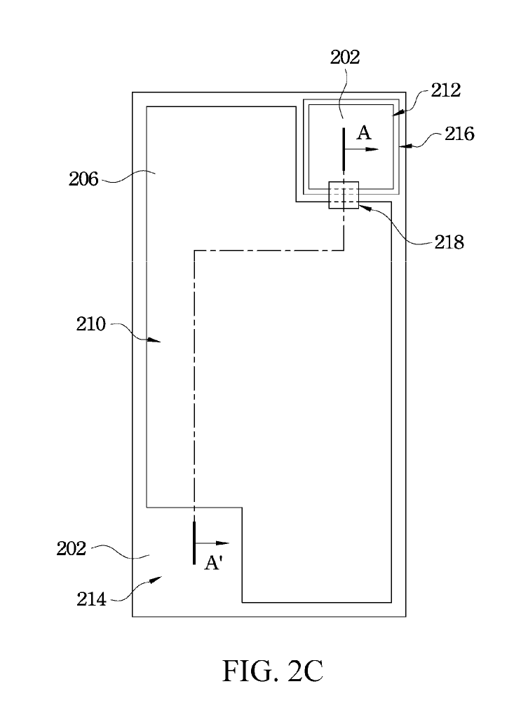

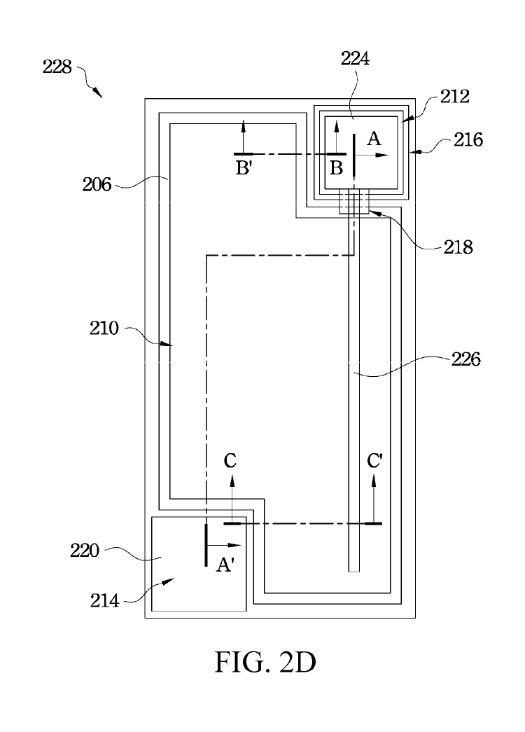

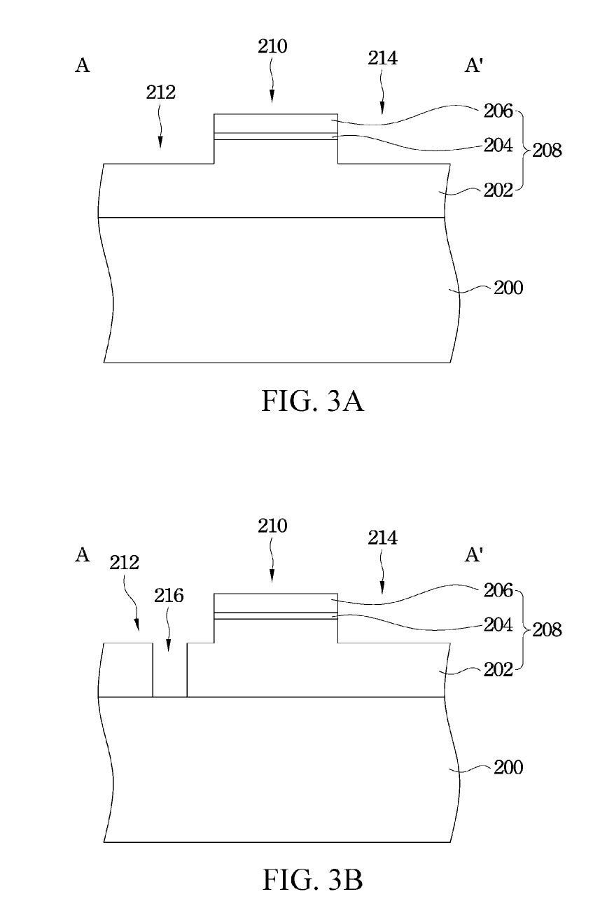

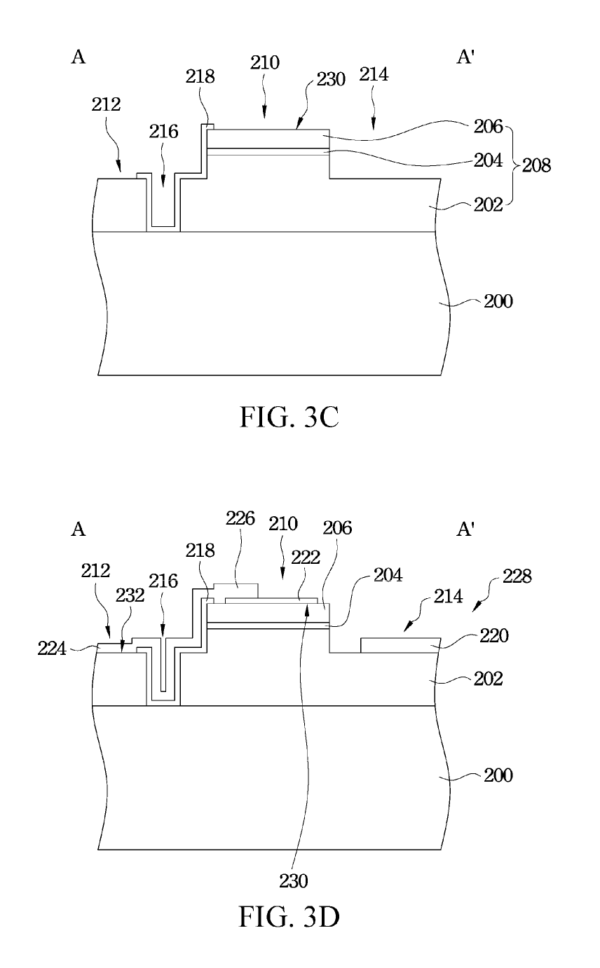

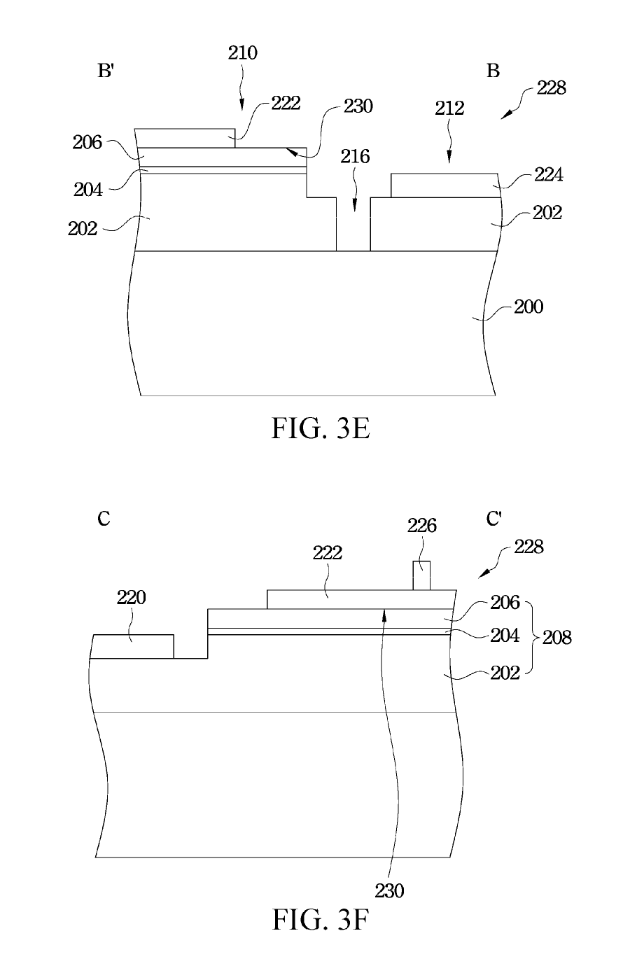

FIG. 2A to FIG. 2D are top views of a process of manufacturing an LED structure according to an embodiment of the present invention. FIG. 3A to FIG. 3D are sectional views of the process of manufacturing an LED structure according to the embodiment of the present invention. Referring to FIG. 2A to FIG. 2D and FIG. 3A to FIG. 3D, in this embodiment, in the process of manufacturing the LED structure 228 (referring to FIG. 3D to FIG. 3F), a substrate 200 is first provided for epitaxy of each material layer of a light-emitting structure 208. In an embodiment, the substrate 200 is an insulating substrate, and a material of the substrate 200 may be, for example, sapphire.

A first electrical semiconductor layer 202, a light-emitting layer 204, and a second electrical semiconductor layer 206 are successively formed on a surface of the substrate 200 through epitaxy, for example, by using organic metal oxide chemical vapor deposition (MOCVD). The first electrical semiconductor layer 202, the light-emitting layer 204, and the second electrical semiconductor layer 206 are successively stacked to form the light-emitting structure 208. A first electrical property is different from a second electrical property. For example, one of the first electrical property and the second electrical property is an n-type, and the other is a p-type. In an embodiment, a material of the light-emitting structure 208 may be, for example, an aluminum indium gallium nitride (AlInGaN) series material. In some examples, the light-emitting layer 204 may be of a multiple quantum well (MQW) structure.

Referring to FIG. 2A and FIG. 3A, the light-emitting structure 208 is pattern-defined through, for example, etching and lithography process to remove a part of the second electrical semiconductor layer 206, a part of the light-emitting layer 204, and a part of the first electrical semiconductor layer 202, so as to form a light-emitting region 210, a first electrode pad region 214, and a second electrode pad region 212 on the light-emitting structure 208. Referring to FIG. 3A, the second electrical semiconductor layer 206 and the light-emitting layer 204 in the first electrode pad region 214 and the second electrode pad region 212 are removed to expose a part of the first electrical semiconductor layer 202. That is to say, both the first electrode pad region 214 and the second electrode pad region 212 are located in an exposed region of the first electrical semiconductor layer 202. In another aspect, the light-emitting region 210 includes the second electrical semiconductor layer 206, the light-emitting layer 204, and the first electrical semiconductor layer 202 and forms a mesa structure.

Referring to FIG. 3B, an isolating trench 216 is formed in the second electrode pad region 212 through, for example, etching and lithography process. The isolating trench 216 penetrates the first electrical semiconductor layer 202 in the second electrode pad region 212 to expose a surface of the substrate 200 below the first electrical semiconductor layer 202, so as to isolate a second electrical electrode pad 224 (referring to FIG. 2D and FIG. 3D) subsequently disposed in the second electrode pad region 212 from the light-emitting region 210. In this embodiment, referring to FIG. 2B and FIG. 2D, the isolating trench 216 is of a frame-shaped structure and entirely surrounds the second electrical electrode pad 224 in the second electrode pad region 212.

An insulating layer 218 is formed through, for example, deposition. Referring to FIG. 2C and FIG. 3C, the insulating layer 218 extends from a part of an upper surface 230 of the second electrical semiconductor layer 206 to a part of the second electrode pad region 212 along a side wall of the light-emitting region 210 and a side wall and a bottom surface of the isolating trench 216. Moreover, in this embodiment, referring to FIG. 2C, the insulating layer 218 only spans a part of the light-emitting region 210 and the second electrode pad region 212. In some embodiments, a material of the insulating layer 218 may include, for example, silicon dioxide (SiO₂), silicon nitride (SiN), aluminum oxide (Al₂O₃), titanium dioxide (TiO₂), spin-on glass (SOG), or a polymer.

Referring to FIG. 3D, a transparent conducting layer 222 may be optionally formed on a part of the upper surface 230 of the second electrical semiconductor layer 206 in the light-emitting region 210 as a current spreading structure. A material of the transparent conducting layer 222 may be, for example, indium tin oxide (ITO), zinc oxide (ZnO), aluminum-doped zinc oxide (AZO), indium-doped zinc oxide (IZO), gallium-doped zinc oxide (GZO), or indium oxide (In₂O₃).

Referring to FIG. 2D and FIG. 3D, a first electrical electrode pad 220, the second electrical electrode pad 224, and a second electrical conducting finger 226 are respectively formed on the first electrode pad region 214, the second electrode pad region 212, and the light-emitting region 210 through, for example, evaporation or deposition, to complete fabrication of the LED structure 228. In this embodiment, squares are substantially taken as examples of shapes of the first electrical electrode pad 220 and the second electrical electrode pad 224, but the present invention is not limited thereto. For example, in other embodiments, the first electrical electrode pad 220 and the second electrical electrode pad 224 may also be of a circular shape or other suitable shapes. Moreover, for convenience of a subsequent wire-bonding process, both the first electrical electrode pad 220 and the second electrical electrode pad 224 require a sufficient area, so that a width of the second electrical electrode pad 224 is greater than that of the second electrical conducting finger 226 connected to the second electrical electrode pad 224. In some embodiments, materials of the first electrical electrode pad 220, the second electrical electrode pad 224, and the second electrical conducting finger 226 may be, for example, a chromium/platinum/aurum (Cr/Pt/Au) laminated layer or an alloy of these metals.

In this embodiment, referring to FIG. 2D and FIG. 3D, the second electrical electrode pad 224 is disposed on the first electrical semiconductor layer 202, so that a bottom surface 232 of the second electrical electrode pad 224 is located below the upper surface 230 of the second electrical semiconductor layer 206. Moreover, the second electrical conducting finger 226 in the light-emitting region 210 is disposed above the upper surface 230 of the second electrical semiconductor layer 206 of the light-emitting structure 208. Furthermore, the second electrical conducting finger 226 extends towards the second electrode pad region 212 and spans the isolating trench 216 to be connected to the second electrical electrode pad 224, referring to FIG. 2D. A segment of the second electrical conducting finger 226 extending through the side wall of the light-emitting region 210 from the upper surface 230 of the second electrical semiconductor layer 206 and spanning the isolating trench 216 to be connected to the second electrical electrode pad 224 extends on the insulating layer 218, and preferably, a projection area of the insulating layer 218 is greater than a projection area of the second electrical conducting finger 226, so as to prevent the second electrical conducting finger 226 from being electrically connected to the light-emitting layer 204 and the first electrical semiconductor layer 202 in the light-emitting region 210 to cause a short circuit in the process of the second electrical conducting finger 226 extending to be connected to the second electrical electrode pad 224.

In this embodiment, the second electrical conducting finger 226 above the light-emitting region 210 covers at least a part of the transparent conducting layer 222. That is to say, the transparent conducting layer 222 may be located between the second electrical conducting finger 226 and the second electrical semiconductor layer 206. In this embodiment, a gap exists between the insulating layer 218 and the transparent conducting layer 222, so that the second electrical conducting finger 226 located above the insulating layer 218 and the transparent conducting layer 222 may directly contact the second electrical semiconductor layer 206 in the gap to achieve electrical connection, or may achieve electrical connection with the second electrical semiconductor layer 206 through the transparent conducting layer 222. In this way, a current transferred downwards through the second electrical conducting finger 226 may be spread by using the transparent conducting layer 222, thereby avoiding a current crowding phenomenon below the second electrical conducting finger 226 in the light-emitting region 210. Moreover, the insulating layer 218 may extend below a part of the second electrical conducting finger 226 above the light-emitting region 210 to provide a current blocking effect.

FIG. 3E is a sectional view of an LED structure taken along a section line BB′ of FIG. 2D. It can be known from FIG. 3E that, in this embodiment, the isolating trench 216 between the second electrode pad region 212 and the light-emitting region 210 taken along the section line BB′ of FIG. 2D is not covered with the insulating layer 218. Referring to FIG. 2D and the foregoing description, the insulating layer 218 is formed on a part of the second electrical semiconductor layer 206 below the second electrical conducting finger 226, on a side wall of a part of the light-emitting region 210 and a part of the isolating trench 216 spanned by the second electrical conducting finger 226 intended to extend to the second electrical electrode pad 224, and on adjacent parts of the foregoing regions.

FIG. 3F is a sectional view of an LED structure taken along a section line CC′ of FIG. 2D. It can be known from FIG. 3D that, in the LED structure 228 of this embodiment, a structure below the second electrical conducting finger 226 in the light-emitting region 210 includes the transparent conducting layer 222, the second electrical semiconductor layer 206, the light-emitting layer 204, the first electrical semiconductor layer 202, and the insulating substrate 200. Moreover, it can be known from FIG. 3D and FIG. 3F that, both the first electrode pad region 214 and the second electrode pad region 212 of the LED structure 228 are disposed on the first electrical semiconductor layer 202. In this way, both the first electrical electrode pad 220 and the second electrical electrode pad 224 are located on the first electrical semiconductor layer 202. Therefore, in the LED structure 228, structures below the first electrical electrode pad 220 and the second electrical electrode pad 224 are the same, and include the first electrical semiconductor layer 202 and the substrate 200.

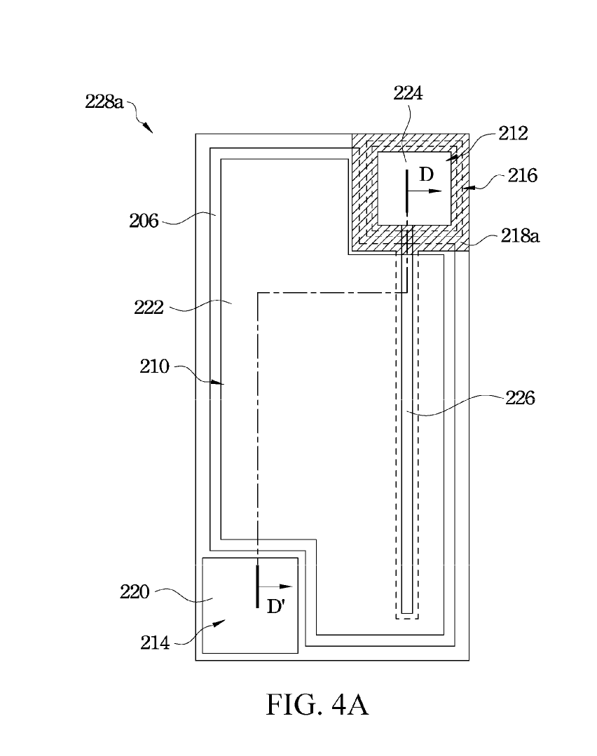

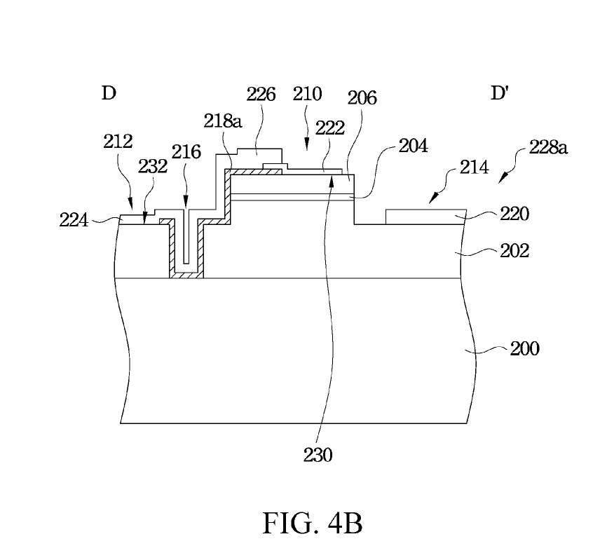

FIG. 4A is a top view of an LED structure according to another embodiment of the present invention, and FIG. 4B is a sectional view of the LED structure taken along a section line DD′ of FIG. 4A. Referring to FIG. 4A and FIG. 4B, in this embodiment, architecture of the LED structure 228a is substantially the same as that of the LED structure 228 of the foregoing embodiment, and the main difference lies in that, an insulating layer 218a of the LED structure 228a is filled in the whole region of the isolating trench 216 and adjacent regions thereof, and the insulating layer 218a further extends below the whole second electrical conducting finger 226 in the light-emitting region 210. Similarly, a material of the insulating layer 218a may include, for example, SiO₂, SiN, Al₂O₃, TiO₂, SOG, or a polymer.

Referring to FIG. 4A and FIG. 4B, in the LED structure 228a, a part of the transparent conducting layer 222 is clamped between the second electrical conducting finger 226 and the insulating layer 218a. The other part of the transparent conducting layer 222 extends on the upper surface 230 of the second electrical semiconductor layer 206. Therefore, in this embodiment, a structure below the second electrical conducting finger 226 in the light-emitting region 210 includes the transparent conducting layer 222, the insulating layer 218a, the second electrical semiconductor layer 206, the light-emitting layer 204, the first electrical semiconductor layer 202, and the substrate 200.

In this embodiment, the insulating layer 218a below the second electrical conducting finger 226 in the light-emitting region 210 may be used as a current blocking layer, so that a current is prevented from being directly injected into the second electrical semiconductor layer 206 below the second electrical conducting finger 226, and the current may be injected by the transparent conducting layer 222 into the second electrical semiconductor layer 206 after being uniformly spread by the transparent conducting layer 222.

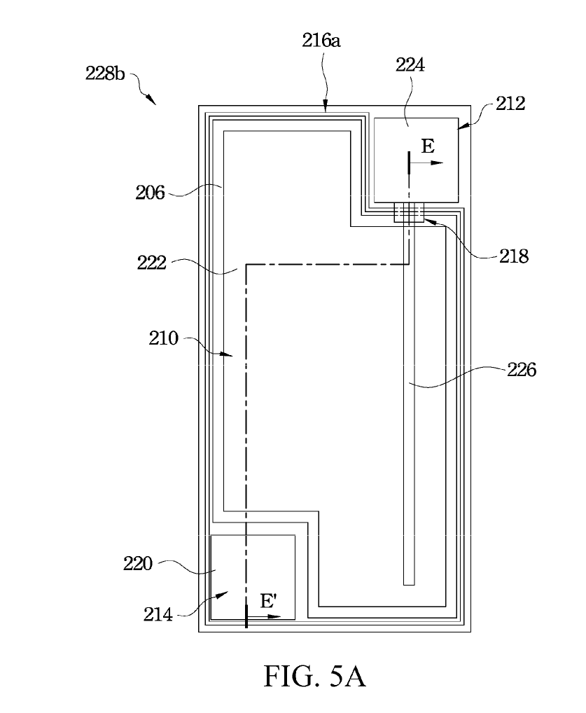

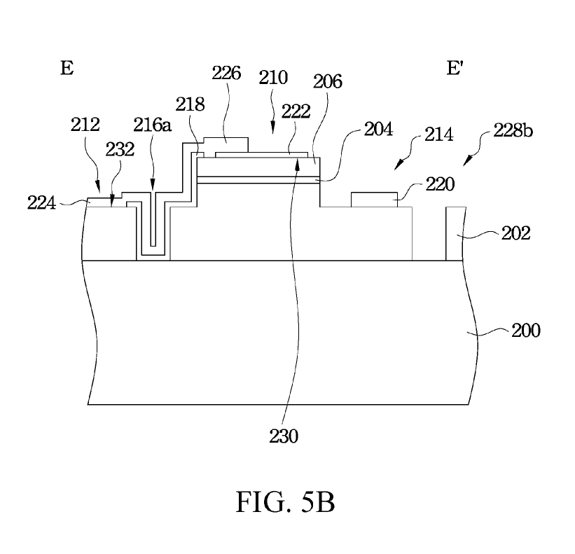

FIG. 5A is a top view of an LED structure according to yet another embodiment of the present invention, and FIG. 5B is a sectional view of the LED structure taken along a section line EE′ of FIG. 5A. Referring to FIG. 5A and FIG. 5B, in this embodiment, architecture of the LED structure 228b is substantially the same as that of the LED structure 228 of the foregoing embodiment, and the main difference lies in that, the isolating trench 216 of the LED structure 228 surrounds the whole outer side of the second electrical electrode pad 224, but an isolating trench 216a of the LED structure 228b entirely surrounds the light-emitting region 210 and the first electrical electrode pad 220 in the first electrode pad region 214. That is to say, the light-emitting region 210 and the first electrical electrode pad 220 in the first electrode pad region 214 are located in the closed isolating trench 216a, and the second electrical electrode pad 224 in the second electrode pad region 212 is located outside the isolating trench 216a.

In the LED structure 228b shown in FIG. 5A, the insulating layer 218 is formed on a part of the second electrical semiconductor layer 206 below the second electrical conducting finger 226, on a side wall of a part of the light-emitting region 210 and a part of the isolating trench 216a spanned by the second electrical conducting finger 226 intended to extend to the second electrical electrode pad 224, and on adjacent parts of the foregoing regions. However, in other embodiments, the insulating layer 218 may also be filled in the isolating trench 216a at two sides of the second electrical electrode pad 224 adjacent to the light-emitting region 210.

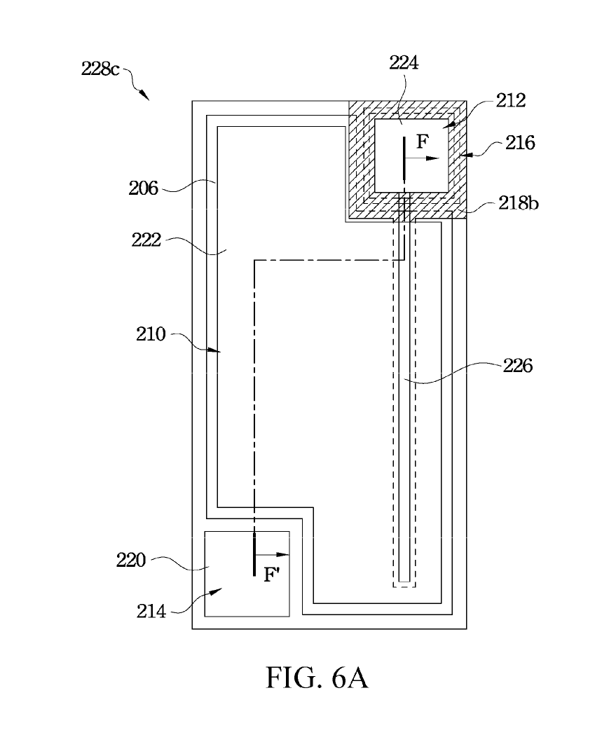

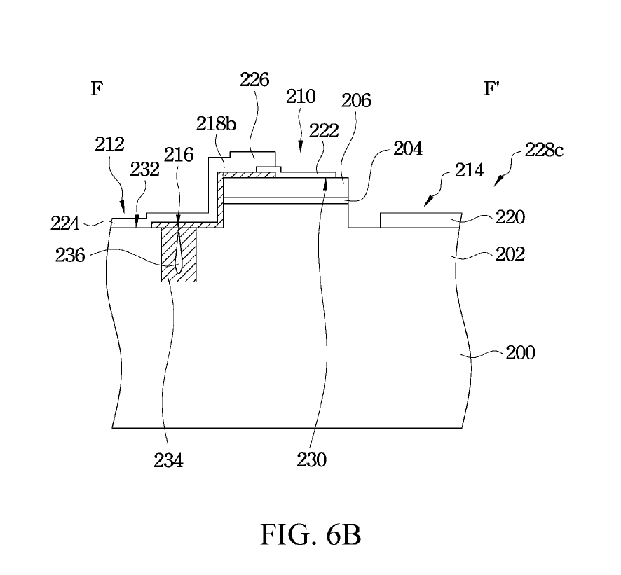

FIG. 6A is a top view of an LED structure according to still another embodiment of the present invention, and FIG. 6B is a sectional view of the LED structure taken along a section line FF′ of FIG. 6A. Referring to FIG. 6A and FIG. 6B, in this embodiment, architecture of the LED structure 228c is substantially the same as that of the LED structure 228a of the foregoing embodiment, and the main difference lies in that, the LED structure 228c includes two insulating layers 218b and 234, and the second electrical conducting finger 226 is not filled in the isolating trench 216.

In the LED structure 228c, the insulating layer 234 is filled in the isolating trench 216. In an embodiment, the isolating trench 216 is preferably filled up with an insulating material, so that the second electrical conducting finger 226 does not need to be filled in the isolating trench 216. In another aspect, the insulating layer 218b extends from the upper surface 230 of the second electrical semiconductor layer 206 in the light-emitting region 210 through the side wall of the light-emitting region 210 and the insulating layer 234 in the isolating trench 216, so as to prevent the second electrical conducting finger 226 from directly injecting a current into the light-emitting region 210. In some examples, referring to FIG. 6B, a void 236 may be generated in the insulating layer 234 in the isolating trench 216 in the filling process, but a conducting material such as the second electrical conducting finger 226 is not filled in the isolating trench 216, so that the void 236 can still maintain the electric insulation property, and does not influence the reliability and performance of the LED structure 228c.

In this embodiment, a material of the insulating layer 218b may be the same as or different from that of the insulating layer 234. In some examples, the material of the insulating layers 218b and 234 may include, for example, SiO₂, SiN, Al₂O₃, TiO₂, SOG, or a polymer.

In the LED structure 228c, the second electrical conducting finger 226 does not need to be filled in the isolating trench 216, so that the disconnection problem of the second electrical conducting finger 226 due to a too high aspect ratio of the isolating trench 216 and undesirable process control can be avoided. Therefore, this embodiment can improve the reliability and the process yield of the LED structure 228c.

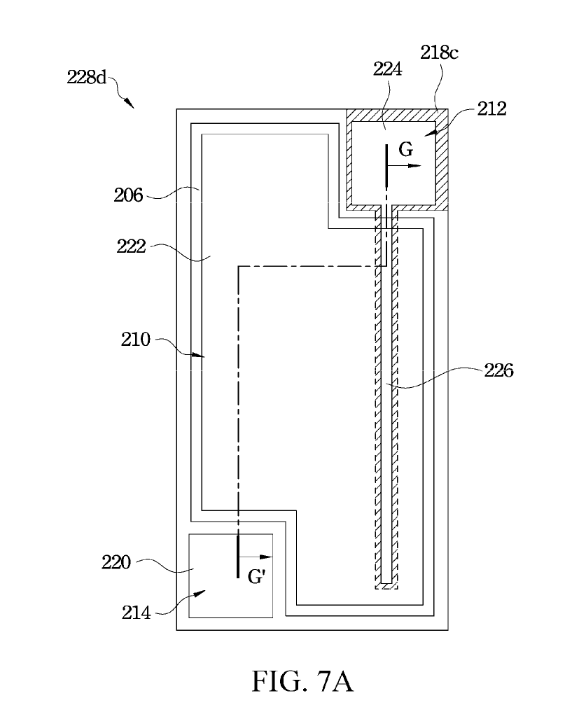

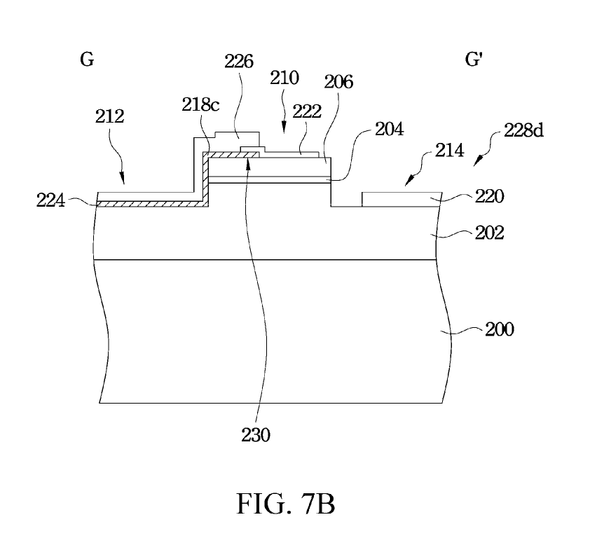

FIG. 7A is a top view of an LED structure according to still another embodiment of the present invention, and FIG. 7B is a sectional view of the LED structure taken along a section line GG′ of FIG. 7A. Referring to FIG. 7A and FIG. 7B, in this embodiment, architecture of the LED structure 228d is substantially the same as that of the LED structure 228c of the foregoing embodiment, and the main difference lies in that, the LED structure 228d does not have the isolating trench, and the insulating layer 218c extends below the whole second electrical electrode pad 224. It can be known from FIG. 7B that, the insulating layer 218c located in the second electrode pad region 212 is substantially located on the same plane since the insulating layer 218c dose not need to be filled in the isolating trench, thereby simplifying the difficulty of depositing the insulating layer. Referring to FIG. 7A, a projection area of the insulating layer 218c is preferably greater than a projection area of the second electrical electrode pad 224 and the second electrical conducting finger 226, to obtain a preferred current blocking effect. Similarly, a material of the insulating layer 218c may include, for example, SiO₂, SiN, Al₂O₃, TiO₂, SOG, or a polymer.

In the LED structure 228d, the insulating layer 218c extends from the upper surface 230 of the second electrical semiconductor layer 206 in the light-emitting region 210 to the second electrode pad region 212 through the side wall of the light-emitting region 210. Moreover, an area of the insulating layer 218c is greater than that of the second electrical electrode pad 224, and the second electrical electrode pad 224 is entirely located on the insulating layer 218c. In this way, the second electrical electrode pad 224 is prevented from directly injecting a current into the first electrical semiconductor layer 202 below the second electrical electrode pad 224, so that the current must be injected into the transparent conducting layer 222 through the second electrical conducting finger 226 in the light-emitting region 210, and then the transparent conducting layer 222 uniformly injects the current into the second electrical semiconductor layer 206.

The LED structure 228d is not disposed with the isolating trench, so the related process cost of forming the isolating trench can be saved, and the second electrical conducting finger 226 does not need to be filled in the isolating trench, thereby avoiding the disconnection problem of the second electrical conducting finger 226 due to undesirable process control. Therefore, this embodiment can reduce the process cost and improve the reliability and the process yield of the LED structure 228d.

In the embodiments, the first electrical electrode pad and the second electrical electrode pad are arranged in opposite angles as an example for illustration. However, in other embodiments, the arrangement of the first electrical electrode pad and the second electrical electrode pad on the LED structure can be adjusted according to design requirements of the LED structure. For example, the first electrical electrode pad and the second electrical electrode pad may be arranged in parallel with a side of the LED structure.

It can be known from the embodiments of the present invention that, among other things, an advantage of the present invention is that, in the LED structure of the present invention, both the first electrical electrode pad and the second electrical electrode pad are disposed on the surface of the first electrical semiconductor layer, and the insulating layer is used to electrically insulate a region below the second electrical electrode pad from the first electrical electrode pad and the light-emitting region, thereby greatly reducing the probability of peeling of the second electrode pad caused by the stress of the material layers, and improving the reliability and the process yield of the LED structure.

It can be known from the embodiments of the present invention that, among other things, another advantage of the present invention is that, in the LED structure of the present invention, the structure layers below the first electrode pad and the second electrode pad are the same, so that the color aberration problem of the electrode pads can be effectively avoided, thereby greatly improving the process yield of the LED structure.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments are chosen and described in order to explain the principles of the invention and their practical application so as to activate others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A light-emitting diode (LED) structure, comprising:
an insulating substrate;
a light-emitting structure, comprising a first electrical semiconductor layer, a light-emitting layer, and a second electrical semiconductor layer successively stacked on the insulating substrate, wherein the light-emitting structure comprises a first electrode pad region, a second electrode pad region, and a light-emitting region, and the first electrical semiconductor layer and the second electrical semiconductor layer have different electrical properties;
a first electrical electrode pad, disposed on the first electrode pad region;
a second electrical electrode pad, disposed on the second electrode pad region, wherein a bottom surface of the second electrical electrode pad is located below an upper surface of the second electrical semiconductor layer;
a second electrical conducting finger, disposed on the light-emitting structure and connected to the second electrical electrode pad, wherein the second electrical conducting finger is electrically connected to the second electrical semiconductor layer; and
a first insulating layer, for insulating the second electrical conducting finger from the first electrical semiconductor layer and the light-emitting layer in the light-emitting region.

2. The LED structure according to claim 1, wherein the light-emitting region comprises a mesa structure formed by the first electrical semiconductor layer, the light-emitting layer, and the second electrical semiconductor layer.

3. The LED structure according to claim 1, wherein a width of the second electrical electrode pad is greater than that of the second electrical conducting finger.

4. The LED structure according to claim 1, wherein both the first electrical electrode pad and the second electrical electrode pad are located on an exposed region of the first electrical semiconductor layer.

5. The LED structure according to claim 1, further comprising a transparent conducting layer, disposed on the second electrical semiconductor layer in the light-emitting region, wherein the transparent conducting layer is located between the second electrical conducting finger and the second electrical semiconductor layer.

6. The LED structure according to claim 5, wherein the first insulating layer extends below a part of the second electrical conducting finger in the light-emitting region.

7. The LED structure according to claim 5, wherein the first insulating layer extends below the whole second electrical conducting finger in the light-emitting region, and a part of the transparent conducting layer is located between the first insulating layer and the second electrical conducting finger.

8. The LED structure according to claim 1, wherein the light-emitting structure comprises an isolating trench, at least located between the second electrical electrode pad and the light-emitting region and penetrating the light-emitting structure to expose a part of the insulating substrate.

9. The LED structure according to claim 8, wherein the isolating trench entirely surrounds the second electrical electrode pad.

10. The LED structure according to claim 8, wherein the isolating trench entirely surrounds the light-emitting region and the first electrical electrode pad.

11. The LED structure according to claim 8, wherein the first insulating layer is formed in at least a part of the isolating trench.

12. The LED structure according to claim 8, wherein the first insulating layer is filled in a whole region of the isolating trench.

13. The LED structure according to claim 8, further comprising a second insulating layer, wherein the second insulating layer is filled in the isolating trench, and the first insulating layer extends through a side wall of the light-emitting region and the second insulating layer from the upper surface of the second electrical semiconductor layer.

14. The LED structure according to claim 1, wherein in the light-emitting region, the second electrical conducting finger is located on a side wall of the light-emitting region and the upper surface of the second electrical semiconductor layer.

15. The LED structure according to claim 1, wherein the first insulating layer extends from the upper surface of the second electrical semiconductor layer to the second electrode pad region through a side wall of the light-emitting region, the first insulating layer located in the second electrode pad region is substantially located on the same plane, and the second electrical electrode pad is entirely located on the first insulating layer.

16. The LED structure according to claim 1, wherein structures below the second electrical electrode pad and the first electrical electrode pad are the same.

17. A method for manufacturing a light-emitting diode (LED) structure, comprising:
forming a light-emitting structure on an insulating substrate, wherein the light-emitting structure is formed to have a first electrical semiconductor layer, a light-emitting layer, and a second electrical semiconductor layer successively stacked on the insulating substrate, and comprises a first electrode pad region, a second electrode pad region, and a light-emitting region, and the first electrical semiconductor layer and the second electrical semiconductor layer have different electrical properties;
forming a first insulating layer extending in a part of the light-emitting region and a part of the second electrode pad region;
forming a first electrical electrode pad on the first electrode pad region;
forming a second electrical electrode pad on the second electrode pad region, wherein a bottom surface of the second electrical electrode pad is located below an upper surface of the second electrical semiconductor layer; and
forming a second electrical conducting finger on the light-emitting structure, wherein the second electrical conducting finger is connected to the second electrical electrode pad and electrically connected to the second electrical semiconductor layer.

18. The method for manufacturing an LED structure according to claim 17, wherein both the first electrical electrode pad and the second electrical electrode pad are located in an exposed region of the first electrical semiconductor layer.

19. The method for manufacturing an LED structure according to claim 17, wherein between the step of forming the light-emitting structure and the step of forming the first insulating layer, the method further comprises the step of forming a transparent conducting layer on the second electrical semiconductor layer in the light-emitting region, wherein the transparent conducting layer is located between the second electrical conducting finger and the second electrical semiconductor layer.

20. The method for manufacturing an LED structure according to claim 19, wherein the first insulating layer extends below a part of the second electrical conducting finger in the light-emitting region.

21. The method for manufacturing an LED structure according to claim 19, wherein the first insulating layer extends below the whole second electrical conducting finger in the light-emitting region, and a part of the transparent conducting layer is located between the first insulating layer and the second electrical conducting finger.

22. The method for manufacturing an LED structure according to claim 17, wherein between the step of forming the light-emitting structure and the step of forming the first insulating layer, the method further comprises the step of forming an isolating trench, at least located between the second electrical electrode pad and the light-emitting region and penetrating the light-emitting structure to expose a part of the insulating substrate.

23. The method for manufacturing an LED structure according to claim 22, wherein between the step of forming the isolating trench and the step of forming the first insulating layer, the method further comprises the step of forming a second insulating layer to be filled in the isolating trench, wherein the first insulating layer extends through a side wall of the light-emitting region and the second insulating layer from the upper surface of the second electrical semiconductor layer.

24. The method for manufacturing an LED structure according to claim 17, wherein the first insulating layer extends from the upper surface of the second electrical semiconductor layer to the second electrode pad region through a side wall of the light-emitting region, the first insulating layer located in the second electrode pad region is substantially located on the same plane, and the second electrical electrode pad is entirely located on the first insulating layer.
